(19) United States
(12) Patent Application Publication
(10) Pub. No.: US 2012/0243147 A1
(43) Pub. Date: Sep. 27, 2012

(54) LAND GRID ARRAY (LGA) CONTACT CONNECTOR MODIFICATION

(75) Inventors: Francesco F. Marconi, Vestal, NY (US); Barry A. Bonitz, Endwell, NY (US); William E. Wilson, Waverly, NY (US)

(73) Assignee: Endicott Interconnect Technologies, Inc., Endicott, NY (US)

(21) Appl. No.: 12/904,305

(22) Filed: Oct. 14, 2010

(51) Int. Cl. H05K 7/00; B23K 1/20; H05K 13/00; B23K 31/02

(52) U.S. Cl. 361/679.01; 228/211; 228/164; 216/13

(57) ABSTRACT

A method of converting a land grid array (LGA) module to a ball grid array (BGA) module by removing and oxidizing portions of the LGA conductive pad features on the upper surface of the LGA module. A BGA solder ball is deposited on the remaining portion of the conductive feature of the LGA module, with subsequent reflowing of the BGA solder ball. By modifying the LGA module to support a BGA structure, excessive heat generated by components placed on the modified LGA pad can be conducted through the BGA structure and into the element on which the LGA module is attached, such as a PCB.

### FIELD OF THE INVENTION

The present invention relates to land grid array (LGA) connectors and more specifically, to a land grid array contact connector modified to utilize ball grid array (BGA) packaging structures.

### BACKGROUND OF THE INVENTION

Land grid array (LGA) modules are becoming one of the most popular modules in the interconnect market. Specifically, as input/output (I/O) requirements and the use of the flip chip have increased, ball grid array (BGA) and column grid array (CGA) modules have become less compatible for assembly. Specifically, the distance from neutral point, I/O density, and similar assembly issues have increased the desirability of LGA modules.

Heretofore, various LGA connectors have been developed for interconnecting LGA modules and PWBs. In general, when an LGA connector is formed, I/O contacts are positioned in a column-row configuration proximate the top surface of the connector. The goal is to obtain the highest quantity of contacts on the LGA connector.

Enhancing commercially available electronic modules with LGA module-to-board connections is required at times when the heat produced by the module is excessive. This excessive heat can be transferred through the connections if BGA style connections are used to connect the module to the board. BGA connections require placing a solder ball on the LGA module pad and reflowing the solder to make a solder joint to connect the module to a printed circuit board. The LGA pads, being in close proximity to one another and non-circular in shape, do not allow for a simple placement of a solder ball on the pad, since reflowing the solder may create a bridge across the gap between adjacent pads and cause an electrical short thereon between. Also, the pad shape being noncircular inhibits the centering of modules placed on the LGA pads with the intent of reflowing solder to attach the module.

In view of the foregoing, there exists a need to modify an existing LGA connector pad and a method for modifying same that maximizes the quality of BGA style I/O contacts on an LGA pad. A further need exists for producing a BGA style connection from an LGA connection for modules that produce excessive heat that will allow the heat to be transferred through the BGA connector to the structure below, such as a printed circuit board. This further allows the modules attached to the BGA connector to be driven to their fullest potential without premature failure due to heat buildup. Still yet, a need exists for creating a circular pad-like structure within the oblong LGA pad to allow for better centering of the BGA, as well as to reduce the potential for the bridging of solder between adjacent pads.

### DISCUSSION OF RELATED ART

In U.S. Pat. No. 7,176,383 by Lauffer et al., issued Feb. 13, 2007 for PRINTED CIRCUIT BOARD WITH LOW CROSS-TALK NOISE, there is defined a printed circuit board and method of making same in which the board includes a common power plane having dielectric layers on opposing sides thereof and a signal layer on each of the dielectric layers, each signal layer having a plurality of substantially parallel signal lines running in substantially similar directions across the signal layers. Predetermined portions of the signal lines in one signal layer are aligned relative to and parallel to corresponding signal lines in another signal layer, with the power plane being located between these portions. Through hole connections are provided between selected signal lines in the two layers, these occurring through clearance holes in the power plane so as to be isolated therefrom. U.S. Pat. No. 7,176,383 is assigned to the same assignee as the present invention.

In U.S. Pat. No. 6,954,984 by McAllister et al., issued Oct. 18, 2005 for LAND GRID ARRAY STRUCTURE, there is described a Land Grid Array structure which includes a flexible film interposer that provides electrical connection between a multi-chip module and the next level of integration, such as a system board, while allowing for engineering change capabilities as well as means for decoupling the power to ground structure to minimize switching activity effects on the overall system using this structure.

U.S. Pat. No. 6,679,707 by Brodsky et al, issued Jan. 20, 2004 for LAND GRID ARRAY CONNECTOR AND METHOD FOR FORMING THE SAME discloses a land grid array connector formed from a plurality of sections. Specifically, each LGA section includes at least one set of fingers and each set of fingers interconnects with a set of fingers of another section to form the LGA connector.

In U.S. Pat. No. 6,638,077 by Fan et al., issued Oct. 28, 2003 for SHIELDED CARRIER WITH COMPONENTS FOR LAND GRID ARRAY CONNECTORS, there is described a shielded carrier with electrical components, resulting in an LGA interposer connector with improved electrical performance and enhanced functionality. The carrier includes components such as resistors and capacitors on and/or in the carrier. The components are preferably of the surface mount variety or are imbedded within the carrier, due to the inherent lower profile of these form factors. Decoupling capacitors and terminating resistors are two examples of components that may improve performance.

In U.S. Pat. No. 6,528,892 by Caletka et al., issued Mar. 4, 2003 for LAND GRID ARRAY STIFFENER USE WITH FLEXIBLE CHIP CARRIERS, there is described a flexible chip carrier with contact pads on its upper surface matching those of the chip. Pads on the lower surface of the chip carrier are conductively connected to LGA pads matching those of a PCB. The chip carrier is provided with a stiffening layer at the LGA interface which is mechanically attached to the lower surface of the chip carrier. Holes are formed in the stiffening layer to expose the LGA pads. The holes are then filled with a conductive adhesive material. Compliant LGA bumps are applied to the uncured conductive adhesive material and the material is then cured.

In U.S. Pat. No. 6,471,525 by Fan et al., issued Oct. 29, 2002 for SHIELDED CARRIER FOR LAND GRID ARRAY CONNECTORS AND A PROCESS FOR FABRICATING SAME, there is described a carrier with electrical shielding of individual contact elements, resulting in an LGA interposer connector with improved electrical performance. The carrier includes a plurality of openings, each of which may contain an individual contact element. The openings may be plated with conductive material, and may also be commoned to one or more reference voltages (e.g., ground) present on at least one conductive layer of the carrier. The carrier may be a single unified structure with a conductive layer on one outer surface, or much more complex, having many layers of dielectric and conductive material.

In U.S. Pat. No. 6,312,266 by Fan et al., issued Nov. 6, 2001 for CARRIER FOR LAND GRID ARRAY CONNECTORS, there is described a carrier that provides improved retention to the individual contact elements resulting in an LGA interposer connector with improved mechanical and electrical performance. In one embodiment, the carrier, which includes upper and lower sections of dielectric material with an adhesive layer in between, includes a plurality of openings, each of which may contain an individual contact element. During assembly of the connector, once the contact elements are inserted, an adhesive layer is reflowed, thereby allowing the carrier to capture the location of the contact elements both with respect to each other as well as to the carrier. Alternately, the carrier may be implemented in a manner that, while not including an adhesive layer to be reflowed, still provides retention of the individual contact elements.

In U.S. Pat. No. 6,137,161 by Gilliland et al., issued Oct. 24, 2000 for INTERPOSER ARRAY MODULE FOR CAPACITIVE DECOUPLING AND FILTERING, there is described a semiconductor package which includes an interposer with upper surface contacts aligned with circuit chip contacts and lower surface contacts aligned with corresponding contacts on a supporting substrate. The interposer includes a series of ground plane layers which are capacitively coupled to the conductors that connect the upper surface contacts to the lower surface contacts. The ground plane layers closest to the circuit chip have plates therebetween and electrically separated therefrom which are connected to the power input supply lines to form decoupling capacitances. The ground plane layers more remote from the circuit chip have, therebetween and electrically separated therefrom, conductive flange portions attached to individual signal lines to form a low pass feed-through filter for each signal line. The capacitance of the flange portions is designed to establish the correct roll off to pass the desired signals and shunt to ground the unwanted harmonics while the decoupling capacitance is sized to afford the required, stabilized power supply.

In U.S. Pat. No. 6,097,611 by Samaras et al., issued Aug. 1, 2000 for MULTI-CHIP LAND GRID ARRAY CARRIER, there is described an LGA carrier which includes an interposer having a first surface and a second surface opposite the first surface, with a plurality of locations on the first surface adapted to receive a plurality of semiconductor dice and passive components. The second surface has a plurality of conductive pads coupled thereto.

In U.S. Pat. No. 6,097,609 by Kabadi, issued Aug. 1, 2000 for DIRECT BGA SOCKET, there is described an electronic packaging assembly in which an electronic component is disposed on a socketing substrate utilizing a ball grid array or LGA. The socketing substrate contains a series of pins embedded within the thickness of the socketing substrate, these pins corresponding to the ball grid array or land grid array contacts of the electronic component. The socketing substrate is mounted onto a motherboard using an array of solder balls that correspond to and are disposed on, the end of the pins facing the motherboard. If desired, a metal lid may protect the electronic component.

In U.S. Pat. No. 5,599,193 by Crotzer, issued Feb. 4, 1997 for RESILIENT ELECTRICAL INTERCONNECT, there is described an electrical interconnector for connecting an integrated circuit or other electrical or electronic component to a circuit board or for interconnecting two or more circuit boards. The interconnector comprises a substrate having one or more resilient elements of a non-conductive material and having opposite contact surfaces. A flexible conductive coating is provided on the contact surfaces of the resilient elements and extends between the contact surfaces to provide electrical connection therebetween. In one embodiment, each element is integrally formed with a resilient substrate and has electrically conductive contact surfaces which are outward of the respective substrate surfaces and are electrically connected through a conductive surface which extends through vias formed in the substrate. In another embodiment, each element is individually formed and is disposed within a corresponding cavity of a separate substrate.

In U.S. Pat. No. 5,530,288 by Stone, issued Jun. 25, 1996 for PASSIVE INTERPOSER INCLUDING AT LEAST ONE PASSIVE ELECTRONIC COMPONENT, there is described an interposer including a first face and second face and at least one electrically conductive plane. The conductive plane functions as a power, ground, or signal plane. At least one electrically insulating plane is positioned on opposite sides of the conductive plane. A plurality of PTHs are formed through the conductive plane and the two insulating planes. The PTHs are selectively electrically joined to the conductive plane. At least one passive electronic structure is positioned within the interposer structure.

It is therefore an object of the invention to provide an assembly modification operation that allows for more successful soldering of BGA structures to an LGA pad.

It is also an object of this invention to use BGA connections to allow excessive heat to be transferred to a component to which the LGA connector will be connected, such as a PCB.

It is also an object of this invention to utilize the creation of a circular gold feature by the partial removal of a gold layer by a laser.

It is also another object of this invention to oxidize the underlying nickel surface using a laser.

It is another object of this invention to utilize the oxidation of the nickel surface to impede the movement of the flowing solder off of the circular BGA pad created.

It is another object of this invention to utilize the circular BGA pad created to center a BGA module to the preferred grid.

### SUMMARY OF THE INVENTION

Generally speaking, the present invention features a method of converting a land grid array (LGA) module to a ball grid array (BGA) module by partially removing and oxidizing portions of the conductive features on the upper surface of the LGA module. A quantity of BGA solder balls are then deposited on the unoxidized portions of the conductive features of the upper surface of the LGA module, with subsequent reflowing of the BGA solder balls. By modifying the LGA module to support BGA, excessive heat generated by components placed on the LGA module is conducted through the BGA and into the element on which the module is attached.

According to a first aspect of the present invention, a commercially available land grid array connector is provided and modified. The modification process removes a portion of pads on a first surface and oxidizes the underlying material. The remaining portion of each pad is circular and receptive to solder ball placement and reflowing. The LGA pad structure is thus converted to a BGA pad structure.

Therefore, the present invention provides an LGA connector and method for forming same.

### BRIEF DESCRIPTION OF THE DRAWINGS

A complete understanding of the present invention may be obtained by reference to the accompanying drawings, when considered in conjunction with the subsequent detailed description, in which:

FIGS. 1-6 are greatly enlarged, partial side sectional elevational views, representing the steps of the present invention of making an LGA connector;

FIG. 7 depicts a top view of an array of lands used on the LGA connector; and

FIG. 8 depicts a top view of the modified lands on the resulting LGA connector.

For the sake of clarity and brevity, like elements and components of each embodiment will bear the same designations throughout the description.

### DESCRIPTION OF THE PREFERRED EMBODIMENT

As indicated above, the present invention provides a land grid array connector converted to a BGA structure and method for forming same. Specifically, an LGA connector is modified using a laser to remove a portion of a gold exterior layer and oxidize underlying nickel material. Solder balls are then placed on the nickel-surrounded gold circular pads and is reflowed to create a solder bump. The oxidized nickel constrains the solder during reflow to keep it within the boundaries of the gold pad.

By the term “circuitized substrate” as used herein is meant a substrate structure having at least one (and preferably more) dielectric layer and at least one external conductive layer positioned on the dielectric layer and including a plurality of conductor pads as part thereof. The dielectric layer(s) may be made of one or more of the following dielectric materials: fiberglass-reinforced epoxy resin (“FR-4”); polytetrafluoroethylene (e.g., Teflon), including polytetrafluoroethylene filled with inorganic particles (e.g., silica) as a means of controlling the coefficient of thermal expansion of the dielectric material; polyimide (e.g., Kapton); polyamide; cyanate resin; photo-imageable material; and other like materials. One example of such material known today is sold under the product name “R02800” by Rogers Corporation, Rogers, Conn. (“R02800” is a trademark of the Rogers Corporation.) The conductive layer(s) preferably serve to conduct electrical signals, including those of the high frequency type, and is preferably comprised of suitable metals such as copper, but may include or comprise additional metals (e.g., nickel, aluminum, etc.) or alloys thereof.

By the term “electroplating” as used herein is meant a process by which a metal in its ionic form is supplied with electrons to form a non-ionic coating on a desired substrate. The most common system involves: a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal.

By the term “electroless plating” (also known as chemical or auto-catalytic plating) as used herein is meant a non-galvanic type of plating method that involves several simultaneous reactions in an aqueous solution, which occur without the use of external electrical power. The reaction is accomplished when hydrogen is released by a reducing agent, normally sodium hypophosphite, and oxidized thus producing a negative charge on the surface of the part.

By the term “laser ablation” as used herein is meant the process of removing material from a solid surface by irradiating it with a laser beam. At low laser flux, the material is heated by the absorbed laser energy and evaporates or sublimes. At high laser flux, the material is typically converted to a plasma. The term laser ablation as used herein refers to removing material with a pulsed laser as well as ablating material with a continuous wave laser beam if the laser intensity is high enough.

By the term “Kapton” as used herein is meant a polyimide material currently available from E.I. du Pont de Nemours & Company (hereinafter also referred to simply as “du Pont”) of Wilmington, Del., and sold under this product name. Kapton is a registered trademark of du Pont.

By the term “thru-hole” as used herein is meant to include what are also commonly referred to in the industry as “blind vias” which are openings typically from one surface of a substrate to a predetermined distance therein, “internal vias” which are vias or openings located internally of the substrate and are typically formed within one or more internal layers prior to lamination thereof to other layers to form the ultimate structure, and “plated thru-holes” (also known as PTHs), which typically extend through the entire thickness of a substrate. All of these various openings form electrical paths through the substrate and often include one or more conductive layers, e.g., plated copper, thereon. Alternatively, such openings may simply include a quantity of conductive paste or, still further, the paste can be additional to plated metal on the opening sidewalls. These openings in the substrate are formed typically using mechanical drilling or laser ablation, following which the plating and/or conductive paste may be added.

Other definitions are readily ascertainable from the detailed descriptions provided herein.

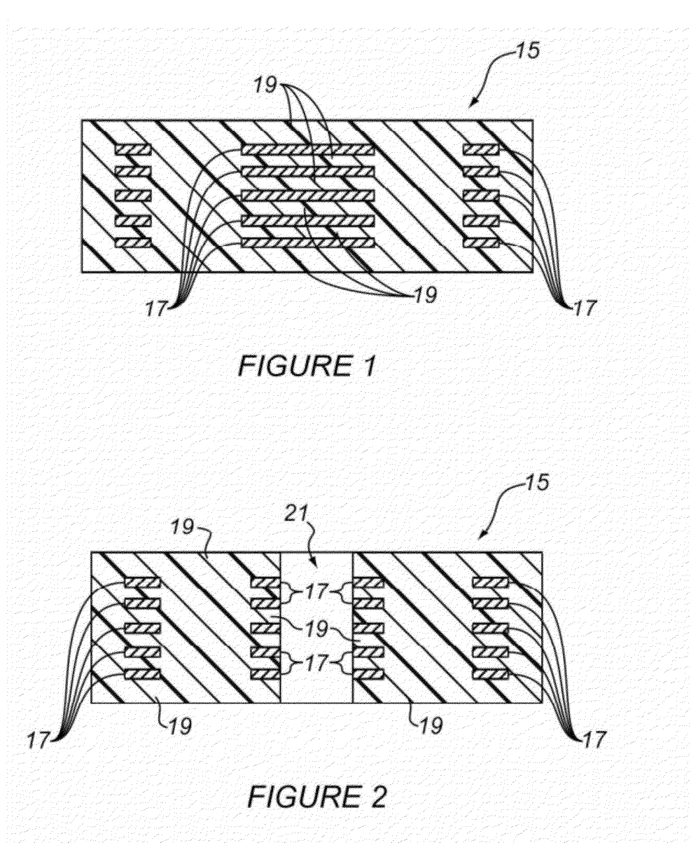

In FIG. 1, a circuitized substrate 15 is shown, this member including a plurality of electrically conductive layers or planes 17 therein. Although five layers 17 are shown, it should be understood that this invention is not limited to the described embodiment, and may have a varied number of layers. Each layer 17 may be a signal, power or ground plane, or combination of these, depending on the operational requirements for the finished product. Circuitized substrate 15 also includes a plurality of layers 19 of dielectric material of the types defined above. Layers 17 and 19 are preferably oriented in an alternating manner, as shown. It is possible to provide two or more dielectric layers as one larger layer, if desired. In one embodiment, each of the five conductive layers 17 may possess a thickness of about 1 mil (0.001 inch), while each of the dielectric layers may be from about 2.5 mils to about 20 mils thick. If a conductive layer is a signal layer, it will typically comprise individual segments (traces or lines) 17. The example shown in FIG. 1 (and in subsequent FIGURES) depicts such a plurality of traces or lines 17 for each of the five conductive layers. If one or more of these layers 19 is to function as power or ground, it would most preferably be solid, not segmented, as depicted. Layers 17 and 19 are bonded together, preferably using conventional lamination processing as is known in the PCB and chip carrier art.

In FIG. 2, a thru-hole 21 is formed within circuitized substrate 15, between opposing surfaces (top and bottom), as shown. That is, the thru-hole 21 extends through the entire thickness of the circuitized substrate 15. Thru-hole 21 may be formed using laser or mechanical drilling, various types of same being known in the PCB art, so further description is not considered necessary. In one embodiment, more than one thru-hole is preferably formed. The invention is not limited to the use of only one thru-hole 21 as shown in FIG. 2. The total number of such thru-holes will thus vary, again depending on the overall size of the final product as well as the desired operational requirements thereof. In one embodiment, thru-hole 21 may have a diameter of 20 mils and extend the full thickness of circuitized substrate 15 which has an overall thickness within the range of from about 20 mils to about 200 mils.

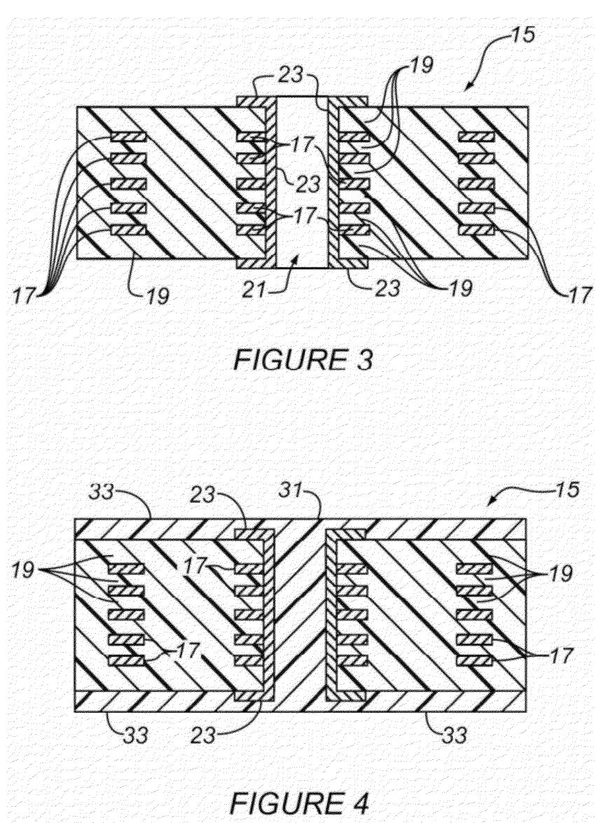

Thru-hole 21 is understood to be of substantially cylindrical configuration, but this is not meant to limit the invention. Thru-hole 21 is also shown to penetrate through a portion of each of the conductive layers 17. This also is not meant to limit the invention, as better understood hereinbelow. That is, any number of such layers 17 may be so connected to layer 23 (FIG. 3). If more than one, each will be of the same electrical potential.

Following formation of thru-hole 21 (which may include cleaning of the interior walls of the circuitized substrate 15, again, using conventional PCB processing), thru-hole 21 is rendered conductive by applying a metal layer 23 to the interior surfaces thereof and, as shown in FIG. 3, to the immediately adjacent exterior surfaces of circuitized substrate 15 about the open end portions of the thru-hole 21. Each of these extending surface portions, if added, are also referred to in the PCB art as “lands.” The invention is not limited to such usage, however, because the internal layer 23 need be located only on the vertical internal surfaces of thru-hole 21. Such lands may be preferred, however, if the respective exterior surfaces on which these reside will also include additional circuitry such as signal lines, some of which may be coupled to respective land segments.

In one embodiment, layer 23 is copper or an alloy thereof and is applied using electroplating. Either electrolytic or electro-less plating may be used for this plating operation. Such methods, like those defined above, are also known in the PCB and chip carrier art, so further description is not deemed necessary. It is within the scope of the invention to provide metals other than copper or copper alloy. Further, added layers such as nickel and a precious metal such as gold may also be applied, as is also known in the art. In one example, layer 23 may possess a thickness of from about 0.5 mil to about 1.5 mils. Significantly, the layer 23 having thru-hole 21 is solid and thus forms a solid wall at a spaced distance around the axis of thru-hole 21. Other conductive thru-holes, if used, provide similar walls at other locations.

FIG. 4 depicts a quantity of dielectric material 31 bonded onto circuitized substrate 15. Such bonding may be accomplished using a conventional PCB lamination process, liquid application or vacuum lamination. Various dielectric materials may be used, with examples including solder mask material and resin-coated copper materials. Examples of solder mask materials include the Valu-SMT® series of materials sold by E.I. duPont de Nemours and Company, the Probimer® solder mask series of materials sold by the Ciba-Geigy Corporation, and the 503B-SH and MR-300RV/-300B series of solder mask materials from Asahi Chemical Research Company. A resin-coated copper material usable for the invention is sold under the product name LG-F-2000G by the LG Chem. Company. Material 31 fills thru-hole 21 and forms a layer 33 on each of the opposite surfaces of circuitized substrate 15, as shown. In one example, each outer layer 33 may possess a thickness of from about 1 mil to about 3 mils. Material 31 is cured and/or dried, if needed, becoming hardened to an extent similar to that of “C-staged” conventional dielectric materials used in many PCB products (e.g., the aforementioned “FR4” material). Material 31 may also be the same as that used for the dielectric layers 19 in circuitized substrate 15.

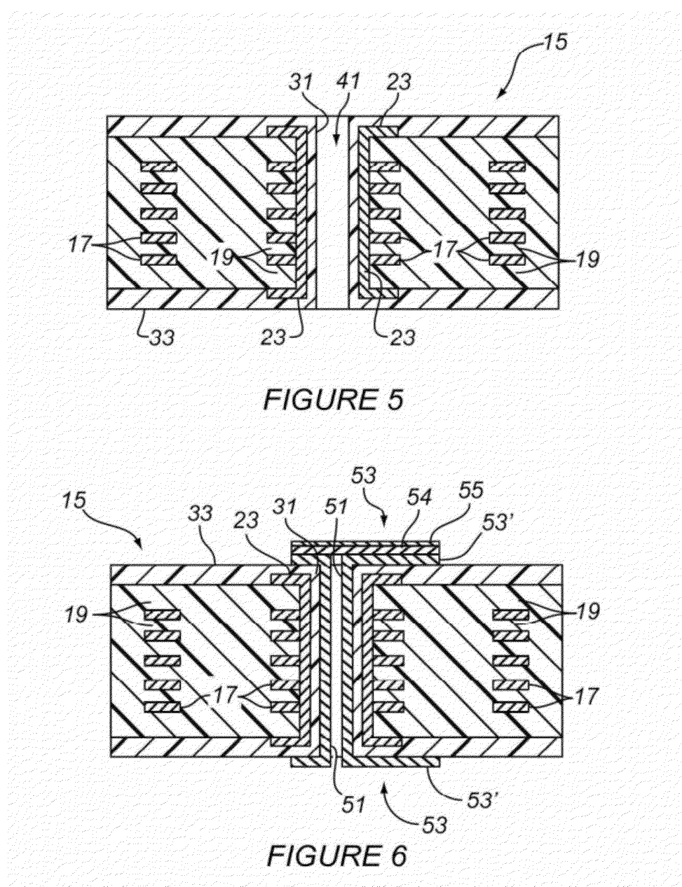

In FIG. 5, a thru-hole 41 is formed within the hardened material 31, preferably using the laser or mechanical drilling that was used for thru-hole 21. In one embodiment, thru-hole 41 may possess a diameter of approximately 12 to 16 mils.

In FIG. 6, a conductive layer 51 is formed on the interior walls of thru-hole 41. In one embodiment, layer 51 is copper or an alloy thereof and is applied using electroplating. Either electrolytic or electro-less plating may be used for this plating operation. Such methods, like those defined above, are also known in the PCB and chip carrier art, so further description is not necessary. It is within the scope of the invention to provide metals other than copper or copper alloy. Further, added layers such as nickel 54 and a precious metal such as gold 55 may also be applied, as is also known in the art.

In one example, layer 51 may be from about 0.5 mil to about 2 mils. Layer 51 extends onto the outer surfaces of material 31 on both opposing sides of the circuitized substrate 15. Such extension may result in the formation of the above mentioned lands in addition to a projecting signal line (or dogbone structure) 53 which may terminate in a pad structure 53′ of about the same thickness as the projecting line but preferably with a larger outer diameter (e.g., preferably cylindrical). In FIG. 6, two such end portions on lines 53 are formed substantially opposite one another. This is not meant to limit the invention as the lines may extend in various directions, including opposing.

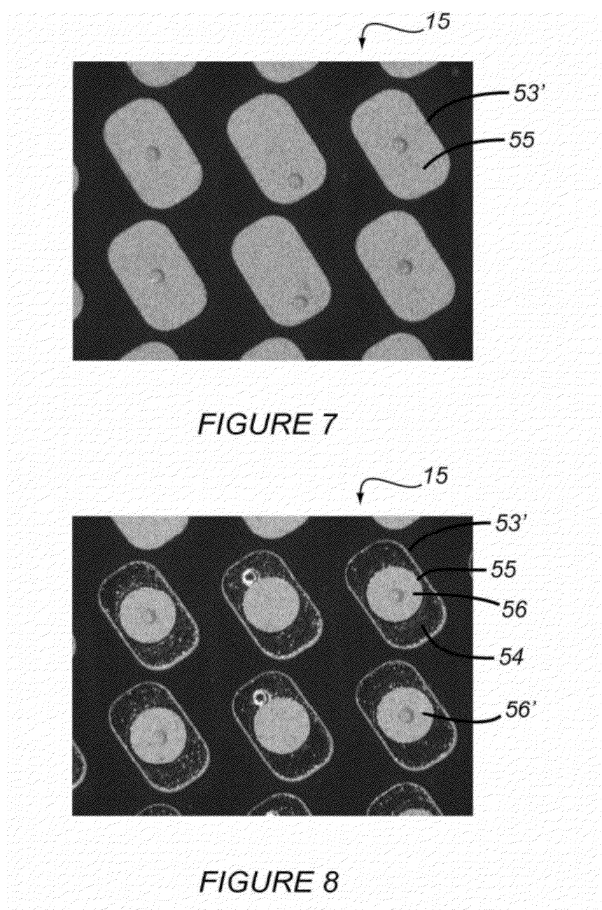

Referring now to FIG. 7, a top view of circuitized substrate 15 is shown containing oblong lands 53 that serve as a base for the BGA style pad. As depicted, circuitized substrate 15 includes individual LGA lands 53′ that connect to signal line 53 and layer 51 inside of circuitized substrate 15. A gold layer 55 constitutes the top layer within the structure of the LGA land 53′.

Gold layer 55 is partially removed using a laser, not shown, as depicted in FIG. 8, exposing the nickel layer 54 thereunder, whereby a circular pad 56 of the remaining gold layer 55 is disposed on nickel layer 54. The process of partially removing the gold layer 55 from LGA land 53′ also oxidizes the nickel layer 54 below it, resulting in a surface that is non-conducive to solder flow, so that when a solder ball, not shown, is placed on the gold circular pad 56 and reflowed, it will not flow excessively and bridge a gap to the next adjacent circular pad 56′.

The foregoing description of the preferred embodiments of this invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

Having thus described the invention, what is desired to be protected by Letters Patent is presented in the subsequently appended claims.

What is claimed is:

1. A method of converting a land grid array (LGA) module having a plurality of pads to a ball grid array (BGA) module, the steps comprising:
a) providing a pad on an LGA module, said pad having an upper conductive surface disposed on a conductive layer, said LGA module comprising a plurality of conductive features;
b) removing portions of said conductive surface of said LGA pad to expose a portion of said conductive layer;
c) oxidizing said exposed portions of said conductive layer;
d) disposing a BGA solder ball on at least one remaining portion of said conductive surface; and
e) reflowing said BGA solder ball.

2. The method of claim 1, the steps further comprising:
f) forming a circular characteristic in said conductive surface on said LGA pad.

3. The method of claim 1, wherein said conductive surface comprises gold, and said conductive layer comprises nickel.

4. The method of claim 3, wherein said conductive layer is disposed on copper.

5. The method of claim 1, wherein said step (b) removing portions of said conductive surface of said LGA pad is accomplished using a technique selected from the group: laser ablation, mechanical milling, and chemical etching.

6. The method of claim 2, wherein said step (f) forming a circular characteristic in said conductive surface is accomplished using a technique selected from the group: laser ablation, mechanical milling, and chemical etching.

7. The method of claim 1, wherein said step (d) disposing a BGA solder ball on said at least one remaining portion of said conductive surface is accomplished using a technique selected from the group: stencil printing, screen printing, doctor blade, and injection deposition.

8. The method of claim 5, wherein said removing portions of said conductive surface is accomplished using a laser selected from the group: UV, Nd:YAG, and CO₂.

9. The method of claim 6, wherein said forming a circular characteristic in said conductive surface is accomplished using a laser selected from the group: UV, Nd:YAG, and CO₂.

10. The method of claim 1, wherein said step (c) oxidizing exposed portions of said conductive layer is accomplished using a laser selected from the group: UV, Nd:YAG, and CO₂.

11. A ball grid array (BGA) module converted from a land grid array (LGA) module having a plurality of pads, comprising:
a) a pad on an LGA module, said pad having an upper conductive surface disposed on a conductive layer, said LGA module comprising a plurality of conductive features;
b) means for removing portions of said conductive surface of said LGA pad to expose a portion of said conductive layer;
c) means for oxidizing said exposed portions of said conductive layer;
d) means for disposing a BGA solder ball on at least one remaining portion of said conductive surface; and
e) means for reflowing said BGA solder ball.

12. The BGA module of claim 11, further comprising:
f) means for forming a circular characteristic in said conductive surface on said LGA pad.

13. The BGA module of claim 11, wherein said conductive surface comprises gold, and said conductive layer comprises nickel.

14. The BGA module of claim 13, wherein said conductive layer is disposed on copper.

15. The BGA module of claim 11, wherein said means for removing said portions of said conductive surface of said LGA pad comprises a tool incorporating a technique selected from the group: laser ablation, mechanical milling, and chemical etching.

16. The BGA module of claim 12, wherein said means for creating circular characteristic in said conductive surface comprises a technique selected from the group: laser ablation, mechanical milling, and chemical etching.

17. The BGA module of claim 11, wherein said means for disposing said BGA solder ball comprises a tool incorporating a technique selected from the group: stencil printing, screen printing, doctor blade, and injection deposition.

18. The BGA module of claim 15, said means for removing portions of said conductive surface comprises a laser selected from the group: UV, Nd:YAG, and CO₂.

19. The BGA module of claim 16, wherein said means for creating said circular characteristic of said conductive surface comprises a laser selected from the group: UV, Nd:YAG, and CO₂.

20. The BGA module of claim 11, wherein said means for oxidizing said exposed portions of said conductive layer comprises a laser selected from the group: UV, Nd:YAG, and CO₂.

21. The BGA module of claim 11, wherein said means for reflowing of said BGA solder ball comprises a tool incorporating a technique selected from the group: infrared (IR), IR convection, hot air pencil, and vapor phase oven.
